(19) United States
(12) Patent Application Publication
(10) Pub. No.: US 2025/0234672 A1
(43) Pub. Date: Jul. 17, 2025

(54) SCHOTTKY-BARRIER PHOTODETECTOR DEVICE WITH GERMANIUM AND IMAGE SENSOR INCLUDING THE PHOTODETECTOR DEVICE

(71) Applicant: SAMSUNG ELECTRONICS CO, LTD., Suwon-si (KR)

(72) Inventors: Chanwook BAIK, Suwon-si (KR); Youngzoon YOON, Suwon-si (KR); Kyungsang CHO, Suwon-si (KR)

(73) Assignee: SAMSUNG ELECTRONICS CO, LTD., Suwon-si (KR)

(21) Appl. No.: 18/984,547

(22) Filed: Dec. 17, 2024

(30) Foreign Application Priority Data
Jan. 17, 2024 (KR) 10-2024-0007633

(51) Int. Cl. H10F 77/14; H10F 30/227; H10F 77/122; H10F 77/20

(52) U.S. Cl. CPC H10F 77/143; H10F 30/2275; H10F 77/122; H10F 77/244

(57) ABSTRACT

A photodetector device includes a germanium semiconductor layer including a plurality of nanostructures at an upper surface of the germanium semiconductor layer, a conductive layer on the plurality of nanostructures, the conductive layer and the germanium semiconductor layer forming a first Schottky junction, and a tunneling barrier layer between the germanium semiconductor layer and the conductive layer.

### CROSS-REFERENCE TO RELATED APPLICATION

This application is based on and claims priority under 35 U.S.C. § 119 to Korean Patent Application No. 10-2024-0007633, filed on Jan. 17, 2024, in the Korean Intellectual Property Office, the disclosure of which is incorporated by reference herein in its entirety.

### BACKGROUND

### 1. Field

The disclosure relates to a Schottky-barrier photodetector device and an image sensor including the Schottky-barrier photodetector device.

### 2. Description of Related Art

In the related art, photodetector devices may employ silicon-based P-N junction techniques for operation in the visible light band. Silicon-based P-N junctions are used in various complementary metal oxide semiconductor (CMOS) image sensors due to characteristics such as a high light absorption rate of silicon especially in the visible light band, excellent photocurrent linearity, high quantum efficiency (about 80%), low noise, and cost reduction by the use of inexpensive silicon. However, photodiodes using silicon-based P-N junctions are not able to absorb photons having energy less than the bandgap energy (about 1.12 eV) of silicon. Therefore, silicon photodiodes or silicon CMOS image sensors using silicon photodiodes are typically used in cameras for visible light (having a wavelength of about 400 nm to about 700 nm).

Silicon does not absorb light well in the near infrared (NIR) band or the short-wavelength infrared (SWIR) band having longer wavelengths than the visible light band.

### SUMMARY

Provided are a photodetector device having an improved light absorption rate and that may be capable of sensing light in a wide wavelength band, and an image sensor including the photodetector device.

Additional aspects will be set forth in part in the description which follows and, in part, will be apparent from the description, or may be learned by practice of the presented embodiments of the disclosure.

According to an aspect of the disclosure, a photodetector device may include a germanium semiconductor layer including a plurality of nanostructures at an upper surface of the germanium semiconductor layer, a conductive layer on the plurality of nanostructures, the conductive layer and the germanium semiconductor layer forming a first Schottky junction, and a tunneling barrier layer between the germanium semiconductor layer and the conductive layer.

The plurality of nanostructures may include nanodisks or nanoholes.

The plurality of nanostructures may be arranged at a period p in a first direction that is parallel to the upper surface of the germanium semiconductor layer, and each nanostructure of the plurality of nanostructures may have a width d in the first direction and a thickness t in a second direction perpendicular to the first direction.

The period p of the plurality of nanostructures may satisfy λ/5<p<λ, where λ corresponds to a wavelength of incident light.

The width d of each nanostructure of the plurality of nanostructures may satisfy λ/4n<d<4λ/n, where λ corresponds to a wavelength of incident light and n corresponds to a refractive index of the germanium semiconductor layer.

The thickness t of each nanostructure of the plurality of nanostructures may satisfy λ/4n<t<4λ/n, where λ corresponds to a wavelength of incident light and n corresponds to a refractive index of the germanium semiconductor layer.

The germanium semiconductor layer may be doped with a dopant.

The photodetector device may include a first semiconductor substrate, and the germanium semiconductor layer may be on the first semiconductor substrate.

The first semiconductor substrate may be of a first conductivity type, the photodetector device further may include a second semiconductor layer between the first semiconductor substrate and the germanium semiconductor layer, and the second semiconductor layer may be of a second conductivity type that is different from the first conductivity type.

The first semiconductor substrate may be doped with a first conductivity type dopant, and a region of the first semiconductor substrate that contacts the germanium semiconductor layer may be doped with a second conductivity type dopant.

The conductive layer may include a metal or a metal oxide.

The conductive layer may include a transparent conductive oxide (TCO).

The photodetector device may include an intermediate layer between the tunneling barrier layer and the conductive layer.

The intermediate layer and the germanium semiconductor layer may form a second Schottky junction, and the intermediate layer may have a work function such that a Schottky barrier height of the second Schottky junction is less than a Schottky barrier height of the first Schottky junction.

A difference between a conduction band energy level of the tunneling barrier layer and an electron affinity of the germanium semiconductor layer may be less than 2 eV.

A bandgap energy of the tunneling barrier layer may be greater than a bandgap energy of the germanium semiconductor layer.

The tunneling barrier layer may include a metal oxide or a silicon oxide.

According to an aspect of the disclosure, an image sensor may include a sensor array including a plurality of light-sensing elements, each light-sensing element of the plurality of light-sensing elements including a photodetector device, and a processor configured to read a photoelectric signal generated by each light-sensing element of the plurality of light-sensing elements, where each photodetector may include a germanium semiconductor layer including a plurality of nanostructures at an upper surface of the germanium semiconductor layer, a conductive layer on the plurality of nanostructures, the conductive layer and the germanium semiconductor layer forming a first Schottky junction, and a tunneling barrier layer between the germanium semiconductor layer and the conductive layer.

Each photodetector device may include an intermediate layer between the tunneling barrier layer and the conductive layer.

The intermediate layer and the germanium semiconductor layer may form a second Schottky junction, and the intermediate layer may have a work function such that a Schottky barrier height of the second Schottky junction is less than a Schottky barrier height of the first Schottky junction.

According to an aspect of the disclosure, a photodetector device may include a germanium semiconductor layer including a plurality of nanostructures at an upper surface of the germanium semiconductor layer, a conductive layer on the plurality of nanostructures, the conductive layer and the germanium semiconductor layer forming a first Schottky junction, and a tunneling barrier layer between the germanium semiconductor layer and the conductive layer, where the germanium semiconductor layer may be doped with an n-type dopant at a first concentration.

The photodetector device may include an intermediate layer between the tunneling barrier layer and the conductive layer, where the intermediate layer and the germanium semiconductor layer may form a second Schottky junction.

The photodetector device may include a first electrode contacting the conductive layer; and a second electrode contacting the germanium semiconductor layer.

The germanium semiconductor layer may include an ohmic contact region doped with an n-type dopant at a second concentration higher than the first concentration, and the second electrode may contact the ohmic contact region of the germanium semiconductor layer.

The photodetector device may include a first electrode contacting the conductive layer, and a second electrode contacting the germanium semiconductor layer, the germanium semiconductor layer may include an ohmic contact region doped with an n-type dopant at a second concentration higher than the first concentration, and the second electrode may contact the ohmic contact region of the germanium semiconductor layer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a cross-sectional view illustrating a photodetector device according to one or more embodiments;

FIG. 2 is a graph illustrating the light absorption rate of a photodetector device according to the thickness of nanostructures, according to one or more embodiments;

FIG. 3 is a graph illustrating the light absorption rate of a photodetector device according to the radius of nanostructures according to one or more embodiments;

FIG. 4 is a cross-sectional view illustrating a photodetector device according to one or more embodiments;

FIG. 5 is a cross-sectional view illustrating a photodetector device according to one or more embodiments;

FIG. 6 is a cross-sectional view illustrating an implementation example of a photodetector device according to one or more embodiments;

FIG. 7 is a cross-sectional view illustrating an implementation example of a photodetector device according to one or more embodiments;

FIG. 8 is an energy band diagram illustrating a state in which a bias voltage is not applied to the implementation examples of the photodetector device that are shown in FIGS. 6 and 7 according to one or more embodiments;

FIG. 9 is an energy band diagram illustrating a state in which a reverse bias voltage is applied to the implementation examples of the photodetector device that are shown in FIGS. 6 and 7 according to one or more embodiments;

FIG. 10 is a cross-sectional view illustrating an implementation example of a photodetector device according to one or more embodiments;

FIG. 11 is a cross-sectional view illustrating an implementation example of a photodetector device according to one or more embodiments;

FIG. 12 is an energy band diagram illustrating a state in which a bias voltage is not applied to the implementation examples of the photodetector device that are shown in FIGS. 10 and 11 according to one or more embodiments;

FIG. 13 is an energy band diagram illustrating a state in which a reverse bias voltage is applied to the implementation examples of the photodetector device that are shown in FIGS. 10 and 11 according to one or more embodiments;

FIG. 14 is a cross-sectional view illustrating an implementation example of a photodetector device according to one or more embodiments;

FIG. 15 is a cross-sectional view illustrating an embodiment of a photodetector device according to one or more embodiments;

FIG. 16 is an energy band diagram illustrating a state in which a bias voltage is not applied to the implementation examples of the photodetector device that are shown in FIGS. 14 and 15 according to one or more embodiments;

FIG. 17 is an energy band diagram illustrating a state in which a reverse bias voltage is applied to the implementation examples of the photodetector device that are shown in FIGS. 14 and 15 according to one or more embodiments;

FIG. 18 is a cross-sectional view illustrating an implementation example of a photodetector device according to one or more embodiments;

FIG. 19 is a cross-sectional view illustrating an implementation example of a photodetector device according to one or more embodiments;

FIG. 20 is an energy band diagram illustrating a state in which a bias voltage is not applied to the implementation examples of the photodetector device that are shown in FIGS. 18 and 19 according to one or more embodiments;

FIG. 21 is an energy band diagram illustrating a state in which a reverse bias voltage is applied to the implementation examples of the photodetector device that are shown in FIGS. 18 and 19 according to one or more embodiments;

FIG. 22 is a cross-sectional view illustrating an image sensor according to one or more embodiments; and

FIG. 23 is a block diagram illustrating a circuit configuration of an image sensor according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, embodiments will be described with reference to the accompanying drawings. The embodiments described herein are for illustrative purposes only, and various modifications may be made therein. In the drawings, like reference numerals refer to like elements, and the sizes of elements may be exaggerated for clarity of illustration.

In the following description, when a component is referred to as being “above” or “on” another component, it may be directly on an upper, lower, left, or right side of the other component while making contact with the other component or may be above an upper, lower, left, or right side of the other component without making contact with the other component.

Terms such as first, second, etc. may be used to describe various components, but are used only for the purpose of distinguishing one component from another component. These terms do not limit the difference in the material or structure of the components.

The terms of a singular form may include plural forms unless otherwise mentioned. It will be further understood that the terms “comprises” and/or “comprising” used herein specify the presence of stated features or elements, but do not preclude the presence or addition of one or more other features or elements.

In addition, terms such as “unit” and “module” described in the specification may indicate a unit that processes at least one function or operation, and this may be implemented as hardware or software, or may be implemented as a combination of hardware and software.

The use of the term “the” and similar designating terms may correspond to both the singular and the plural.

Operations of a method may be performed in appropriate order unless explicitly described in terms of order or described to the contrary. In addition, examples or exemplary terms (for example, “such as” and “etc.”) are used for the purpose of description and are not intended to limit the scope of the disclosure unless defined by the claims.

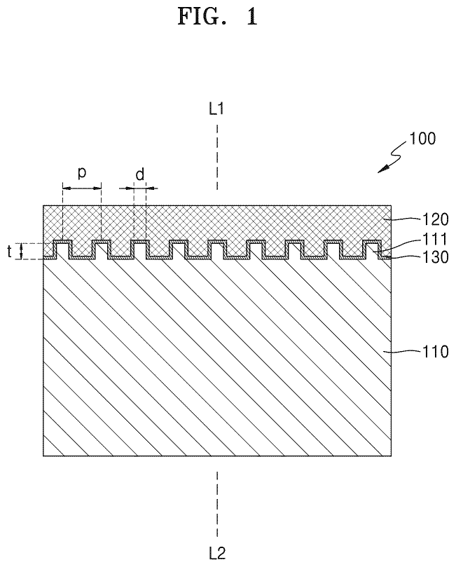

FIG. 1 is a cross-sectional view illustrating a photodetector device according to one or more embodiments.

Referring to FIG. 1, the photodetector device 100 may include a germanium (Ge) semiconductor layer 110, a conductive layer 120 provided above the Ge semiconductor layer 110, and a tunneling barrier layer 130 provided between the Ge semiconductor layer 110 and the conductive layer 120. A Schottky junction (i.e., a Schottky junction structure) may be formed between the Ge semiconductor layer 110 and the conductive layer 120. The Ge semiconductor layer 110 may include a plurality of nanostructures 111 provided on an upper surface thereof.

The Ge semiconductor layer 110 may include Ge. The Ge semiconductor layer 110 may include amorphous-Ge or crystalline-Ge (for example, epitaxially grown Ge). The Ge semiconductor layer 110 may include GeₓSn₁₋ₓ (0<x<1). The Ge semiconductor layer 110 may be undoped or may be doped with a dopant. The Ge semiconductor layer 110 may include undoped i-Ge (intrinsic-Ge), p-Ge that is lightly doped with a p-type dopant, or n-Ge that is lightly doped with an n-type dopant. For example, the doping concentration of p-Ge may be about 10¹³/cm³ to about 10¹⁸/cm³, and the p-type dopant may be B, Al, Ga, In, or Te. For example, the doping concentration of n-Ge may be about 10¹³/cm³ to about 10¹⁸/cm₃, and the n-type dopant may be P, As, or Sb.

Silicon (Si) photodiodes including Si P-N junctions are not able to absorb photons having energy less than the bandgap energy of Si. Si photodiodes or Si complementary metal oxide semiconductor (CMOS) image sensors including Si photodiodes have high quantum efficiency in a visible light band (a wavelength band of about 400 nm to about 700 nm) and are thus mostly used in visible-light cameras. However, Si does not absorb light well in a near infrared (NIR) band (a wavelength band of about 700 nm to about 1600 nm), and thus, it is difficult to use Si photodiodes as NIR sensors. Because the bandgap energy of Ge is less than the bandgap energy of Si, Ge is able to absorb light in a wavelength band of about 800 nm to about 3000 nm (for example, about 800 nm to about 1700 nm), and thus, Ge photodiodes may be used as NIR sensors or short wavelength infrared (SWIR) sensors.

Therefore, the photodetector device 100 may be configured such that light absorption mainly occurs in the Ge semiconductor layer 110 containing Ge, and thus, the photodetector device 100 may absorb infrared light in the NIR or SWIR band (a wavelength band of about 800 nm to about 3000 nm) with high optical efficiency.

A Schottky junction photodiode may be implemented instead of a P-N junction diode by providing the conductive layer 120 on the Ge semiconductor layer 110 containing Ge. Photocurrent may be generated in a wide wavelength band of about 800 nm to about 3000 nm with high quantum efficiency by appropriately selecting the work function and energy level of the Ge semiconductor layer 110 and the work function and energy level of the conductive layer 120. In this case, when the energy of light incident on the photodetector device 100 is greater than the bandgap energy of Ge, a photocurrent may be generated with high efficiency by interband transition in the Ge semiconductor layer 110. In addition, when the energy of light incident on the photodetector device 100 is greater than a Schottky barrier height, hot carriers may be generated in the conductive layer 120 by an internal photoemission effect, and thus, a photocurrent may be generated. Because photocurrent is generated by these two effects, high quantum efficiency may be guaranteed. In addition, the photodetector device 100 using a Schottky junction may be driven at a lower voltage level than a photodetector device using a Si P-N junction when a reverse voltage is applied thereto, and may have a high switching speed because high-speed switching between forward and reverse bias voltages is possible. In addition, the photodetector device 100 using a Schottky junction may be manufactured through simpler processes than a photodetector device using a P-N junction and may thus incur low mass production costs.

The conductive layer 120 may form a Schottky junction together with the Ge semiconductor layer 110. The conductive layer 120 may cover the nanostructures 111 of the Ge semiconductor layer 110. The conductive layer 120 may include a metal, an alloy, a metal nitride, a silicide, a transparent conductive oxide (TCO), or the like. The metal may include, for example, Au, Al, Ag, Cu, Pt, Ni, W, Ti, Cr, Mo, Ru, Ge, Ta, Hf, Nb, Zr, or V. The alloy may include, for example, AlNd. The metal nitride may include, for example, TiN, AlN, TaN, Ta₂N, Ta₃N₅, W₂N, WN, or WN₂. The silicide may include, for example, TiSi, TiSi₂, Ti₅Si₃, VSi₂, FeSi₂, CoSi₂, PtSi, Pt₂Si, NiSi, NiSi₂, Ni₂Si, Cu₃Si, YSi, ZrSi, NbSi₂, MoSi₂, PdSi, Pd₂Si, ErSi, YbSi, YbSi₂, ZrSi₂, HfSi, HfSi₂, TaSi, TaSi₂, NbSi, NbSi₂, ZrSi, ZrSi₂, VSi, VSi₂, WSi, WSi₂, GeSi, OsSi, IrSi, IrSi₃, AlSi, CuSi, RuSi, or Ru₂Si₃. The TCO may include, for example, indium tin oxide (ITO), indium tungsten oxide (IWO), indium zinc oxide (IZO), gallium doped zinc oxide (GZO), gallium indium zinc oxide (GIZO), aluminum doped zinc oxide (AZO), or the like. However, the materials listed above are just examples and embodiments are not limited thereto.

Light may be incident on the conductive layer 120 or the Ge semiconductor layer 110. In the case in which light L1 is incident on the conductive layer 120, the conductive layer 120 may include a TCO. The conductive layer 120 may have a small thickness such that the incident light L1 may pass through the conductive layer 120. For example, the thickness of the conductive layer 120 may be about 200 nm or less. For example, the thickness of the conductive layer 120 may be 100 nm or less or 5 nm or less. In the case in which light L2 is incident on the Ge semiconductor layer 110, the conductive layer 120 may have a thickness for preventing the light L2 from passing through the Ge semiconductor layer 110. In this case, the light L2 incident on the conductive layer 120 through the Ge semiconductor layer 110 may be reflected by the conductive layer 120 back to the Ge semiconductor layer 110.

A portion of the light L1 or light L2 may be absorbed by the Ge semiconductor layer 110, and another portion of the light L1 or light L2 may be absorbed by the conductive layer 120. Photons absorbed in the conductive layer 120 may generate photocurrent by an internal quantum emission effect. Photons absorbed in the Ge semiconductor layer 110 may generate photocurrent with high efficiency by interband transition. Based on these two mechanisms, a wide light absorption band and a high degree of quantum efficiency may be realized. In addition, light absorption may occur in the SWIR band depending on the Schottky barrier height (i.e., energy) between the conductive layer 120 and the Ge semiconductor layer 110.

The energy band diagram of a photodetector device using a Schottky barrier shows a steep slope because of a very small thickness of a Schottky barrier structure and the occurrence of energy band bending. As a result, leakage current may occur by quantum mechanical tunneling. That is, due to field emission occurring between the Ge semiconductor layer 110 and the conductive layer 120, carriers having energy less than the Schottky barrier height may pass through the Schottky barrier. These carriers may correspond to a dark current flowing without incident light and may cause noise in a photodetector device or an image sensor including the photodetector device. Therefore, the performance of photodetector devices or image sensors including photodetector devices may be improved by suppressing dark current as much as possible.

The photodetector device 100 may include the tunneling barrier layer 130 between the conductive layer 120 and the Ge semiconductor layer 110. The tunneling barrier layer 130 may increase the thickness of a Schottky barrier while having little or a small effect on the Schottky barrier height, thereby reducing or preventing leakage current that may occur due to quantum mechanical tunneling. To have less influence on the Schottky barrier height, the tunneling barrier layer 130 may include a material having a conduction band energy level similar to the electron affinity of the Ge semiconductor layer 110. That is, the tunneling barrier layer 130 may include a material having a conduction band energy level similar to that of the Ge semiconductor layer 110. For example, the difference between the conduction band energy level of the tunneling barrier layer 130 and the conduction band energy level of the Ge semiconductor layer 110 (that is, the electron affinity of the Ge semiconductor layer 110) may be less than 2 eV.

In addition, the bandgap energy of the tunneling barrier layer 130 may be greater than the bandgap energy of the Ge semiconductor layer 110 to reduce or prevent dark current. For example, the bandgap energy of the tunneling barrier layer 130 may be greater than about 2 eV. The tunneling barrier layer 130 may include a metal oxide semiconductor having wide-bandgap energy. The metal oxide semiconductor may include, for example, SnO₂, ZnO, WO₃, Nb₂O₅, BaSnO₃, Zn₂SO₄, SrTiO₃, BaTiO₃, Zn₂Ti₃O₈, SiO₂, Al₂O₃, HfO₂, MgO, MoO₃, Fe₃₂O₃, Ta₂O₅, TaON, or In₂O₃. The metal oxide semiconductor may include TiO₂, TiO₂₋ₓ (0<x<1), TiO, Ti₂O, Ti₃O, Ti₂O₃, or TiₙO₂ₙ₋₁ (n refers to an integer ranging from 3 to 9). The tunneling barrier layer 130 may include, for example, at least one of metal oxides and Si oxides.

The thickness of the tunneling barrier layer 130 may be determined to reduce or prevent dark current. The thickness of the tunneling barrier layer 130 may be about 30 nm or less. When the thickness of the tunneling barrier layer 130 is greater than 30 nm, it may be difficult for carriers to move through the tunneling barrier layer 130 in normal conditions. Therefore, the thickness of the tunneling barrier layer 130 may be less than or equal to, for example, 10 nm, to secure the mobility of carriers.

According to one or more embodiments, the nanostructures 111 may be provided at the upper surface of the Ge semiconductor layer 110. The nanostructures 111 may be provided between the Ge semiconductor layer 110 and the tunneling barrier layer 130. The nanostructures 111 may have various shapes. For example, the nanostructures 111 may be shaped as a plurality of nanodisks protruding from the upper surface of the Ge semiconductor layer 110 as shown in FIG. 1.

The nanostructures 111 may be arranged with a period p in a direction parallel to the upper surface of the Ge semiconductor layer 110. The period p may refer to a distance between the center of each nanostructure 111 or a distance between a same point on each nanostructure 111. The nanostructures 111 may have a width d in the direction parallel to the upper surface of the Ge semiconductor layer 110. The nanostructures 111 may have a thickness t in a direction perpendicular to the upper surface of the Ge semiconductor layer 110. The period p, width d, and thickness t of the nanostructures 111 may be less than the wavelength λ of incident light. Due to the nanostructures 111 having a period p, a width d, and a thickness t that are each less than the wavelength λ of light incident on the Ge semiconductor layer 110, the light absorption rate of the Ge semiconductor layer 110 may be improved.

According to one or more embodiments, the Ge semiconductor layer 110 of the photodetector device 100 may include the nanostructures 111 that are smaller than the wavelength λ of incident light, and thus, the light absorption rate of the inside of the Ge semiconductor layer 110 may be improved in a wide wavelength band by an electric field confinement effect. Factors such as the period p, size (width d, radius r or thickness t), shape, cross-sections, and arrangement of the nanostructures 111 may be appropriately selected to effectively improve the light absorption rate of the inside of the Ge semiconductor layer 110.

For example, when the wavelength of incident light is λ, the period p of the nanostructures may satisfy λ/5<p<λ. For example, when the wavelength of incident light is) and the refractive index of the Ge semiconductor layer 110 is n, the width d of the nanostructures 111 may satisfy λ/4n<d<4λ/n. For example, when the wavelength of incident light is A and the refractive index of the Ge semiconductor layer 110 is n, the thickness t of the nanostructures 111 may satisfy λ/4n<t<4λ/n.

The period p, width d, and thickness t of the nanostructures 111 may be constant or non-constant. The period p between adjacent nanostructures 111 may be constant or may vary. In addition, the nanostructures 111 may have the same width d or different widths d. In addition, the nanostructures 111 may have the same thickness t or different thicknesses t.

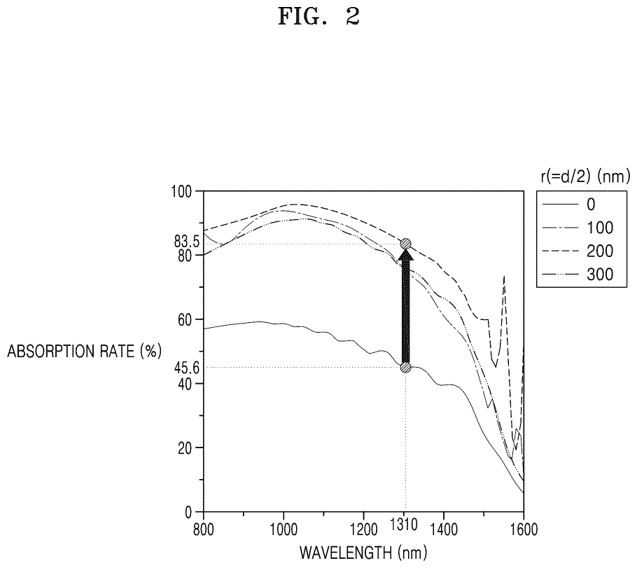

FIG. 2 is a graph illustrating the light absorption rate of a photodetector device according to the radius of nanostructures, according to one or more embodiments. The description of FIG. 2 may refer to aspects of FIG. 1, but the embodiments are not limited thereto. In FIG. 2, the thickness of the Ge semiconductor layer 110 is 2 μm, the thickness of the conductive layer 120 is 100 nm, the thickness of the tunneling barrier layer 130 is 5 nm, and the thickness t of the nanostructures 111 is 300 nm. FIG. 2 illustrates the light absorption rate of the photodetector device 100 when the thickness t of the nanostructures 111 is 0 nm, 100 nm, 200 nm, and 300 nm. In FIG. 2, the radius r of the nanostructures 111 being 0 nm refers to the case in which the nanostructures 111 are not provided on the Ge semiconductor layer 110.

Referring to FIG. 2, the light absorption rate of the photodetector device 100 is greatly improved in most of a wavelength band (for example, 800 nm to 1600 nm) when the Ge semiconductor layer 110 of the photodetector device 100 includes the nanostructures 111 compared to the case in which the Ge semiconductor layer 110 of the photodetector device 100 does not include the nanostructures 111. For example, at a wavelength of about 1310 nm, the light absorption rate of the photodetector device 100 is 45.6% when the Ge semiconductor layer 110 does not include the nanostructures 111 and 83.5% when the Ge semiconductor layer 110 includes the nanostructures 111 and the radius r of the nanostructures 111 is 200 nm. That is, the light absorption rate of the photodetector device 100 is increased by a factor of about 1.83.

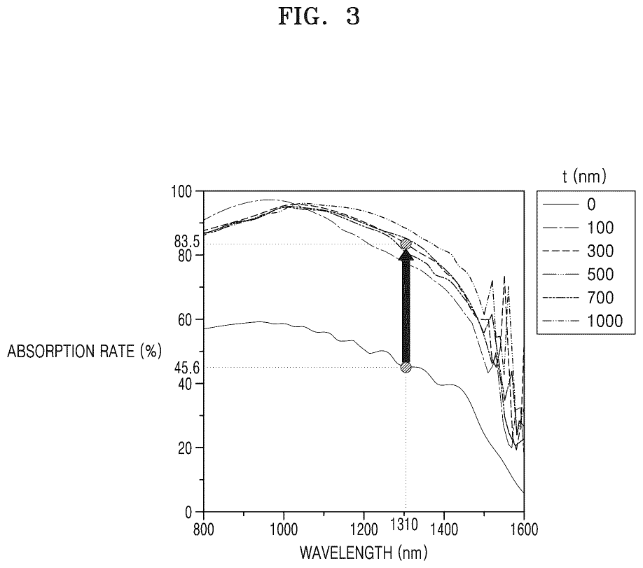

FIG. 3 is a graph illustrating the light absorption rate of a photodetector device according to the thickness of nanostructures according to one or more embodiments. The description of FIG. 3 may refer to aspects of FIG. 1, but the embodiments are not limited thereto. In FIG. 3, the thickness of the Ge semiconductor layer 110 is 2 μm, the thickness of the conductive layer 120 is 100 nm, the thickness of the tunneling barrier layer 130 is 5 nm, and the radius r of the nanostructures 111 is 200 nm. FIG. 3 illustrates the light absorption rate of the photodetector device 100 when the thickness t of the nanostructures 111 is 0 nm, 100 nm, 300 nm, 500 nm, 700 nm, and 1000 nm. In FIG. 3, the thickness t of the nanostructures 111 being 0 nm refers to the case in which the nanostructures 111 are not provided on the Ge semiconductor layer 110.

Referring to FIG. 3, the light absorption rate of the photodetector device 100 is greatly improved in a wavelength band of about 800 nm to about 1600 nm when the Ge semiconductor layer 110 of the photodetector device 100 includes the nanostructures 111 compared to the case in which the Ge semiconductor layer 110 of the photodetector device 100 does not include the nanostructures 111. For example, at a wavelength of about 1310 nm, the light absorption rate of the photodetector device 100 is 45.6% when the Ge semiconductor layer 110 does not include the nanostructures 111 and 83.5% when the Ge semiconductor layer 110 includes the nanostructures 111 and the thickness t of the nanostructures 111 is 300 nm. That is, the light absorption rate of the photodetector device 100 is increased by a factor of about 1.83.

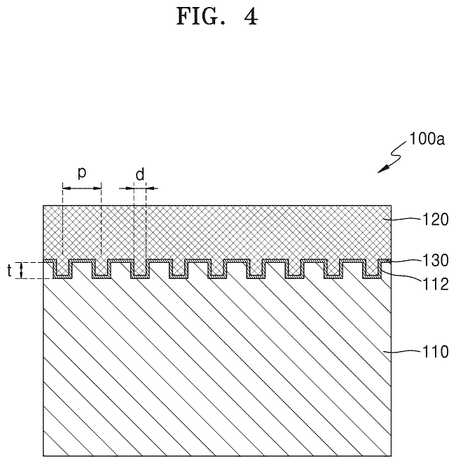

FIG. 4 is a cross-sectional view illustrating a photodetector device 100a according to one or more embodiments.

Referring to FIG. 4, a Ge semiconductor layer 110 may include a plurality of nanoholes 112. The nanoholes 112 may be arranged with a period p in a direction parallel to an upper surface of the Ge semiconductor layer 110. The nanoholes 112 may have a width d in the direction parallel to the upper surface of the Ge semiconductor layer 110. The nanoholes 112 may have a thickness t in a direction perpendicular to the upper surface of the Ge semiconductor layer 110. The nanoholes 112 may be provided by etching the upper surface of the Ge semiconductor layer 110 by an amount corresponding to the thickness t of the nanoholes 112. Embodiments described below may be similarly applied to the case in which the Ge semiconductor layer 110 includes the nanoholes 112.

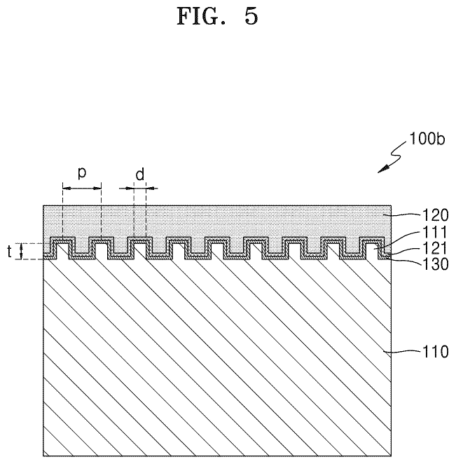

FIG. 5 is a cross-sectional view illustrating a photodetector device 100b according to one or more embodiments.

Referring to FIG. 5, the photodetector device 100 may further include an intermediate layer 121 between a conductive layer 120 and a tunneling barrier layer 130. The intermediate layer 121 may form a Schottky junction structure together with a Ge semiconductor layer 110. The intermediate layer 121 may include a metal, an alloy, a metal nitride, a silicide, or the like. The metal may include, for example, Au, Al, Ag, Cu, Pt, Ni, W, Ti, Cr, Mo, Ru, Ge, Ta, Hf, Nb, Zr, or V. The alloy may include, for example, AlNd. The metal nitride may include, for example, TiN, AlN, TaN, Ta₂N, Ta₃N₅, W₂N, WN, or WN₂. The silicide may include, for example, TiSi, TiSi₂, Ti₅Si₃, VSi₂, FeSi₂, CoSi₂, PtSi, Pt₂Si, NiSi, NiSi₂, Ni₂Si, Cu₃Si, YSi, ZrSi, NbSi₂, MoSi₂, PdSi, Pd₂Si, ErSi, YbSi, YbSi₂, ZrSi₂, HfSi, HfSi₂, TaSi, TaSi₂, NbSi, NbSi₂, ZrSi, ZrSi₂, VSi, VSi₂, WSi, WSi₂, GeSi, OsSi, IrSi, IrSi₃, AISi, CuSi, RuSi, or Ru₂Si₃.

The conductive layer 120 provided on the intermediate layer 121 may be a light-transmissive conductive layer that has light transmittance and high electrical conductivity. For example, the conductive layer 120 may include a TCO that is transparent to light in a visible-to-infrared band. The TCO may include, for example, ITO, IWO, IZO, GZO, GIZO, or AZO.

The intermediate layer 121 may have a work function different from the work function of the conductive layer 120. To reduce a Schottky barrier height, the work function of the intermediate layer 121 may be determined by considering materials included in the conductive layer 120 and the Ge semiconductor layer 110 that are adjacent to the intermediate layer 121. The Schottky barrier height refers to the amount of energy necessary for carriers formed in the intermediate layer 121 or the conductive layer 120 by incident light to move to the Ge semiconductor layer 110. For example, the work function of the intermediate layer 121 may be determined such that the Schottky barrier height of a Schottky junction between the intermediate layer 121 and the Ge semiconductor layer 110 may be less than the Schottky barrier height of a Schottky junction between the conductive layer 120 and the Ge semiconductor layer 110. Due to the intermediate layer 121 provided between the conductive layer 120 and the tunneling barrier layer 130 to lower a Schottky barrier height, light having a low energy level may be detected.

The work function of the intermediate layer 121 may be determined depending on the material and conductivity type (n-type or p-type) of the Ge semiconductor layer 110 and the work function of the conductive layer 120. For example, when the Ge semiconductor layer 110 is an n-type layer, the work function of the intermediate layer 121 may satisfy Equation (1) below, the Schottky barrier height may be expressed by Equation (2) below. For example, when the Ge semiconductor layer 110 is a p-type layer, the work function of the intermediate layer 121 may satisfy Equation (3) below, and the Schottky barrier height may be expressed by Equation (4) below. In Equations (1)-(4), φ_{M} refers to the work function of the conductive layer 120, φ_{Mi} refers to the work function of the intermediate layer 121, χs refers to the electron affinity of the Ge semiconductor layer 110, and E_{g} refers to the bandgap energy of the Ge semiconductor layer 110.

$${φ}_{M} > {φ}_{Mi} > {χ}_{S} \qquad ( 1 )$$

$${φ}_{B} = {φ}_{Mi} - {χ}_{S} \qquad ( 2 )$$

$${φ}_{M} < {φ}_{Mi} < {χ}_{S} + {E}_{g} \qquad ( 3 )$$

$${φ}_{B} = {E}_{g} - ( {φ}_{Mi} - {χ}_{S} ) \qquad ( 4 )$$

For example, when the conductive layer 120 includes ITO and the Ge semiconductor layer 110 includes n-Ge, the intermediate layer 121 may include TiN. However, this is merely an example, and embodiments are not limited thereto.

The intermediate layer 121 may include a metal nitride such as AlN, TaN, Ta₂N, Ta₃N₅, W₂N, WN, or WN₂, or may include a material having a relatively low work function such as Ta, Al, Ti, Mo, V, Mn, Nb, or Mo. For example, when the conductive layer 120 includes ITO and the Ge semiconductor layer 110 includes p-Ge, the intermediate layer 121 may include Cu or Ni. The thickness of the intermediate layer 121 may be determined such that light incident through the conductive layer 120 may pass through the intermediate layer 121. The thickness of the intermediate layer 121 may be about 100 nm or less. For example, the thickness of the intermediate layer 121 may be 50 nm or less or 5 nm or less. Similar to the intermediate layer 121, the conductive layer 120 may have a thickness of about 200 nm or less. For example, the thickness of the conductive layer 120 may be 100 nm or less or 5 nm or less.

The internal quantum efficiency of the intermediate layer 121 may be affected by the thickness of the intermediate layer 121. For example, as the thickness of the intermediate layer 121 increases, the efficiency of photoexcited carrier generation may decrease, and many photons may be reflected by a surface of the intermediate layer 121, resulting in a decrease in internal quantum efficiency. Therefore, the intermediate layer 121 may have a small thickness to prevent a decrease in quantum efficiency, and the work function and energy level of each of the Ge semiconductor layer 110, the intermediate layer 121, and the conductive layer 120 may be determined to generate photocurrent with high quantum efficiency in a wide band including the NIR band and the SWIR band. In addition, a portion of incident light may be absorbed by the intermediate layer 121 and the conductive layer 120, and another portion of the incident light may be absorbed by the Ge semiconductor layer 110. Photons absorbed in the intermediate layer 121 and the conductive layer 120 generate photocurrent by internal quantum emission. Photons absorbed in the Ge semiconductor layer 110 generate photocurrent by a photovoltaic effect. Due to these two mechanisms, a wide light absorption band including the NIR band and the SWIR band may be realized, and quantum efficiency may be improved.

Hereinafter, various implementation examples of the photodetector devices described above and operations thereof will be described. The various implementation examples of the photodetector devices include various shapes of the Ge semiconductor layers, various connection structures between electrodes and the photodetector devices.

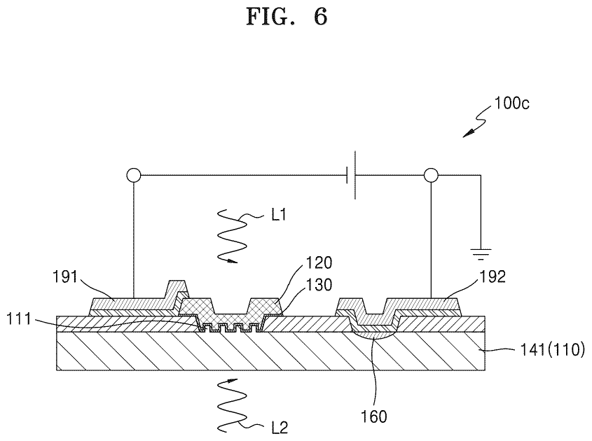

FIG. 6 is a cross-sectional view illustrating an implementation example of a photodetector device 100c according to one or more embodiments.

Referring to FIG. 6, a p-type or n-type doped Ge substrate (for example, an n-Ge substrate 141 doped with an n-type dopant) may be provided as the Ge semiconductor layer 110. The tunneling barrier layer 130 and the conductive layer 120 may be sequentially provided on the n-Ge substrate 141. The nanostructures 111 may be provided on the n-Ge substrate 141.

In the case of a top light incident structure in which light L1 is incident from an upper side of the conductive layer 120, the conductive layer 120 may include a light-transmissive metal oxide having high light transmittance such as ITO. In the case of a bottom light incident structure in which light L2 is incident from a lower side of the n-Ge substrate 141, the conductive layer 120 may include a thick metal material such as a thick metal oxide semiconductor material to prevent the light L2 from passing through the conductive layer 120. First and second electrodes 191 and 192 may be provided on the n-Ge substrate 141 at a distance from each other to apply an electric signal to the Schottky junction structure or measure an electric signal generated by the Schottky junction structure. The first electrode 191 may contact the conductive layer 120. The second electrode 192 may contact the n-Ge substrate 141. The first and second electrodes 191 and 192 may have various shapes for contact with the conductive layer 120 and the n-Ge substrate 141 while securing an opening through which light is incident on the conductive layer 120. For example, an ohmic contact region 160 that is doped with an n-type dopant at a higher concentration than other regions may be provided in a region of the n-Ge substrate 141, and the second electrode 192 may contact the ohmic contact region 160.

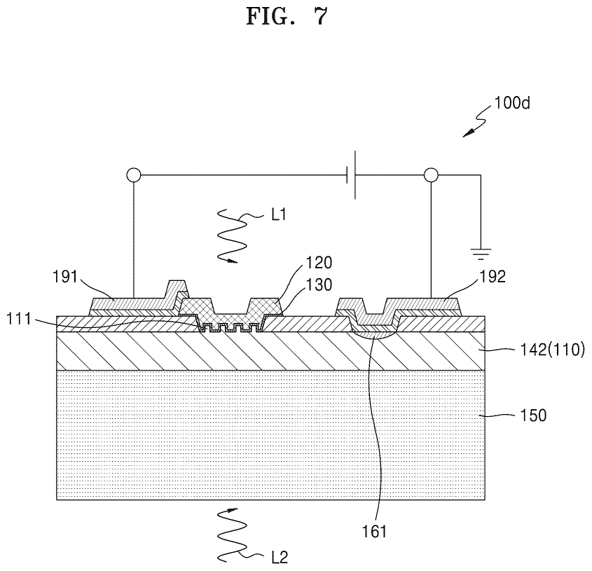

FIG. 7 is a cross-sectional view illustrating an implementation example of a photodetector device 100d according to one or more embodiments.

Referring to FIG. 7, the Ge semiconductor layer 110 may be formed on, for example, a semiconductor substrate 150. The Ge semiconductor layer 110 may include an amorphous-Ge layer or a crystalline-Ge (for example, epitaxially grown Ge) layer. The Ge semiconductor layer 110 may include GeₓSn₁₋ₓ (0<x<1). The Ge semiconductor layer 110 may be undoped or may be doped with a dopant. The Ge semiconductor layer 110 may be an undoped i-Ge (intrinsic-Ge) layer, an n-Ge layer (lightly n-doped Ge layer) that is lightly doped with an n-type dopant, or a p-Ge layer (lightly p-doped Ge layer) that is lightly doped with a p-type dopant. For example, the doping concentration of the p-Ge layer may be about 10¹³/cm₃ to about 10¹⁸/cm₃, and the p-type dopant may be B, Al, Ga, In, or Te. For example, the doping concentration of the n-Ge layer may be about 10¹³/cm₃ to about 10¹⁸/cm₃, and the n-type dopant may be P, As, or Sb. In one or more embodiments, the Ge semiconductor layer 110 may be an n-Ge layer 142 doped with an n-type dopant. The semiconductor substrate 150 may be, for example, a p-Si substrate or an n-Si substrate. Alternatively, the semiconductor substrate 150 may be, for example, a p-Ge substrate or an n-Ge substrate. The nanostructures 111 may be provided on the n-Ge layer 142. The tunneling barrier layer 130 and the conductive layer 120 may be sequentially provided on the n-Ge layer 142.

In the case of a top light incident structure in which light L1 is incident from the upper side of the conductive layer 120, the conductive layer 120 may include a light-transmissive metal oxide having high light transmittance such as ITO. In the case of a bottom light incident structure in which light L2 is incident from the lower side of the semiconductor substrate 150, the conductive layer 120 may include a thick metal or metal oxide to prevent the light L2 from passing through the conductive layer 120. First and second electrodes 191 and 192 may be provided on the n-Ge layer 142 to apply an electric signal to the Schottky junction structure or measure an electric signal generated by the Schottky junction structure. The first electrode 191 may contact the conductive layer 120. The second electrode 192 may contact the n-Ge layer 142. For example, an ohmic contact region 161 doped with an n-type dopant at a higher concentration than other regions may be provided in a region of the n-Ge layer 142, and the second electrode 192 may contact the ohmic contact region 161.

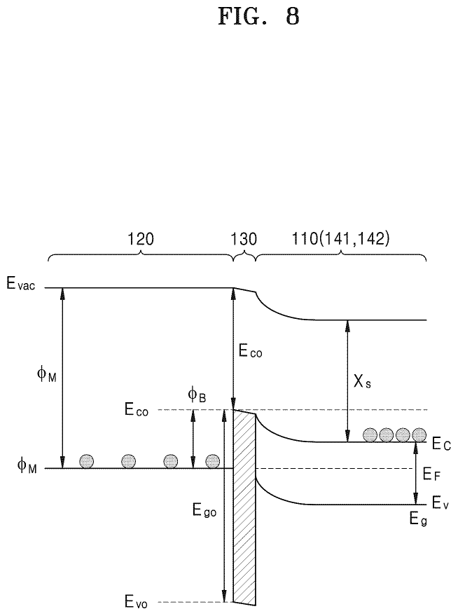

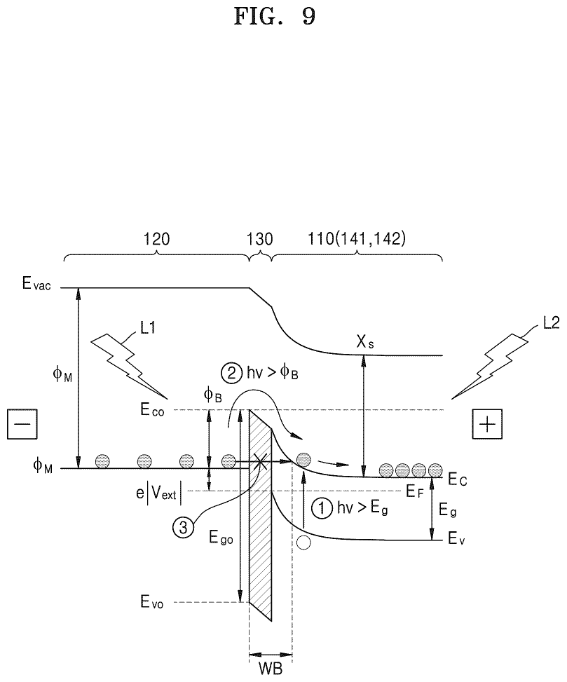

FIG. 8 is an energy band diagram illustrating a state in which a bias voltage is not applied to the implementation examples of the photodetector device that are shown in FIGS. 6 and 7 according to one or more embodiments. FIG. 9 is an energy band diagram illustrating a state in which a reverse bias voltage is applied to the implementation examples of the photodetector device that are shown in FIGS. 6 and 7 according to one or more embodiments. The definitions of symbols shown in FIGS. 8 and 9 are as follows.
φ_{M}: The work function of the conductive layer 120;
φ_{B}: Schottky barrier height;
E_{vac}: Vacuum energy level;
E_{co}: The conduction band energy level of the tunneling barrier layer 130;
Eᵥₒ: The valence band energy level of the tunneling barrier layer 130;
E_{go}: The bandgap energy of the tunneling barrier layer 130;
E_{c}: The conduction band energy level of the Ge semiconductor layer 110;
Eᵥ: The valence band energy level of the Ge semiconductor layer 110;
E_{F}: The Fermi energy level of the Ge semiconductor layer 110;
E_{g}: The bandgap energy of the Ge semiconductor layer 110;
χₛ: The electron affinity of the Ge semiconductor layer 110;
e|Vext|: Energy by a reverse bias voltage; and
hv: Energy of incident light.

For example, in FIGS. 8 and 9, the Ge semiconductor layer 110 includes n-Ge, the conductive layer 120 includes ITO, and the tunneling barrier layer 130 includes TiO₂. The bandgap energy E_{g} of Ge is 0.67 eV, the electron affinity χₛ of Ge is about 4.0 eV, and the work function φ_{M} of ITO is about 4.7 eV. The Schottky barrier height φ_{B}=φ_{M}−χₛ=4.7 eV−4.0 eV=0.7 eV.

When a reverse bias voltage is applied, the Fermi energy level E_{F} of the Ge semiconductor layer 110 falls by the amount of energy (e|Vext|) provided by the reverse bias voltage as shown in FIG. 9. Ge has less bandgap energy than Si, thereby facilitating the absorption of NIR or SWIR rays. Therefore, when the energy of incident light is greater than the bandgap energy of the Ge semiconductor layer 110 (hv>Eg) as indicated by reference numeral \textcircled{1} in FIG. 9, photocurrent flowing by interband transition is detectable. In addition, when the energy of incident light is greater than the Schottky barrier height φ_{B} formed between the conductive layer 120 or the intermediate layer 121 and the Ge semiconductor layer 110 (hv>φ_{B}) as indicated by reference numeral \textcircled{2} in FIG. 9, the conductive layer 120 may absorb some of the incident light, and thus, hot carriers are formed by the internal quantum emission effect, generating a photocurrent.

Referring to FIG. 9, when the tunneling barrier layer 130 is not provided, some of majority carriers having energy less than the Schottky barrier height may move from the conductive layer 120 to the Ge semiconductor layer 110 through the Schottky barrier by quantum mechanical tunneling even though there is no incident light, generating a dark current.

When the tunneling barrier layer 130 includes TiO₂, the conduction band energy level E_{co} of the tunneling barrier layer 130 provided between the conductive layer 120 and the Ge semiconductor layer 110 is about −4.0 eV, substantially the same of the electron affinity χs of Ge of the Ge semiconductor layer 110 that is also about 4.0 eV. Therefore, the tunneling barrier layer 130 has substantially no effect on the Schottky barrier height between the conductive layer 120 and the Ge semiconductor layer 110. In addition, the thickness of the Schottky barrier is increased by the tunneling barrier layer 130 as indicated by WB in FIG. 9. As a result, as indicated by reference numeral \textcircled{3} in FIG. 9, electron tunneling is reduced or prevented, and thus, dark current may be reduced or prevented.

The bandgap energy E_{g} of Ge of the Ge semiconductor layer 110 is about 0.67 eV. The valence band energy level Eᵥₒ of TiO₂ of the tunneling barrier layer 130 is about −7.2 eV, and the conduction band energy level E_{co} of TiO₂ of the tunneling barrier layer 130 is about −4.0 eV. Thus, the bandgap energy E_{go} of TiO₂ of the tunneling barrier layer 130 may be 3.2 eV (E_{go}=|Evo−Eco|=|(−7.2 eV)−(−4.0 eV)|=3.2 eV), which is greater than the bandgap energy E_{g} of Ge. Therefore, the tunneling barrier layer 130 may prevent the occurrence of dark current because the tunneling barrier layer 130 does not absorb light in an infrared band.

In addition, according to one or more embodiments, the Ge semiconductor layer 110 may include the nanostructures 111 having a period, a width, and a thickness that are each less than the wavelength of incident light, and thus, the light absorption rate of the inside of the Ge semiconductor layer 110 may be improved in a wide wavelength band (for example, in the NIR or SWIR band) due to the electric field confinement effect.

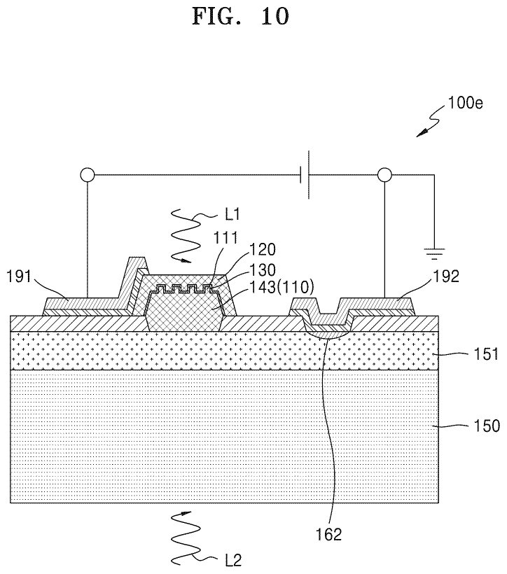

FIG. 10 is a cross-sectional view illustrating an implementation example of a photodetector device 100e according to one or more embodiments.

Referring to FIG. 10, the photodetector device 100e may further include a semiconductor substrate 150 above which the Ge semiconductor layer 110 is provided. The photodetector device 100e may further include a semiconductor layer 151 provided between the semiconductor substrate 150 and the Ge semiconductor layer 110. The semiconductor substrate 150 and the semiconductor layer 151 may include the same material. Alternatively, the semiconductor substrate 150 and the semiconductor layer 151 may include different materials. The semiconductor substrate 150 and the semiconductor layer 151 may be doped with different types of dopants. The semiconductor substrate 150 may be a first conductivity type semiconductor substrate, and the semiconductor layer 151 may be a second conductivity type semiconductor layer. For example, the semiconductor substrate 150 may be doped with one of an n-type dopant and a p-type dopant, and the semiconductor layer 151 may be doped with the other. The semiconductor substrate 150 may be, for example, a p-type doped Si substrate. The semiconductor layer 151 may be, for example, an n-type doped Si layer.

The Ge semiconductor layer 110 may include an amorphous-Ge layer or a crystalline-Ge (for example, epitaxially grown Ge) layer. The Ge semiconductor layer 110 may include GeₓSn₁₋ₓ (0<x<1). The Ge semiconductor layer 110 may be undoped or may be doped with a dopant. The semiconductor layer 110 may be an undoped i-Ge (intrinsic-Ge) layer, an n-Ge layer (lightly n-doped Ge layer) that is lightly doped with an n-type dopant, or a p-Ge layer (lightly p-doped Ge layer) that is lightly doped with a p-type dopant. In one or more embodiments, the Ge semiconductor layer 110 may be an n-Ge layer 143 containing n-Ge. The tunneling barrier layer 130 and the conductive layer 120 may be sequentially provided on the n-Ge layer 143.

In the case of a top light incident structure in which light L1 is incident from the upper side of the conductive layer 120, the conductive layer 120 may include a light-transmissive metal oxide having high light transmittance such as ITO. In the case of a bottom light incident structure in which light L2 is incident from the lower side of the semiconductor substrate 150, the conductive layer 120 may include a thick metal or metal oxide semiconductor to prevent light from passing though the conductive layer 120. First and second electrodes 191 and 192 may be formed on the semiconductor layer 151 to apply an electric signal to the Schottky junction structure or measure an electric signal generated by the Schottky junction structure. The first electrode 191 may contact the conductive layer 120. The second electrode 192 may contact the semiconductor layer 151. For example, an ohmic contact region 162 doped with an n-type dopant at a higher concentration than other regions may be provided in a region of the semiconductor layer 151, and the second electrode 192 may contact the ohmic contact region 162.

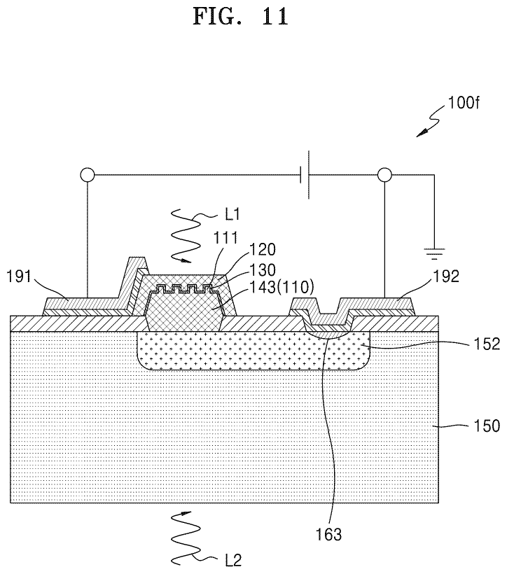

FIG. 11 is a cross-sectional view illustrating an implementation example of a photodetector device 100f according to one or more embodiments. Compared to the implementation example of the photodetector device 100e shown in FIG. 10, the implementation example of the photodetector device 100f shown in FIG. 11 is different in having a doped region 152 in a semiconductor substrate 150, and the Ge semiconductor layer 110 is formed on the doped region 152. Therefore, the description given with reference to FIG. 10 may also applied to the implementation example shown in FIG. 11 unless contradictory thereto, and thus, differences are mainly described below.

Referring to FIG. 11, the semiconductor substrate 150 and the doped region 152 may be doped with different types of dopants. The semiconductor substrate 150 may be doped with a first conductivity type dopant, and the doped region 152 may be doped with a second conductivity type dopant. For example, the semiconductor substrate 150 may be doped with one of an n-type dopant and a p-type dopant, and the doped region 152 may be doped with the other. For example, the semiconductor substrate 150 may be a p-type doped Si substrate. For example, the doped region 152 may be an n-type doped region, that is, an n-well region. The Ge semiconductor layer 110 may be an n-Ge layer 143 containing Ge, for example, n-Ge. The tunneling barrier layer 130 and the conductive layer 120 are sequentially provided on the n-Ge layer 143. An intermediate layer 121 may be further provided between the tunneling barrier layer 130 and the conductive layer 120. A first electrode 191 may contact the conductive layer 120. A second electrode 192 may contact the doped region 152. For example, an ohmic contact region 163 doped with an n-type dopant at a higher concentration than other regions may be formed in a region of the doped region 152, and the second electrode 192 may contact the ohmic contact region 163.

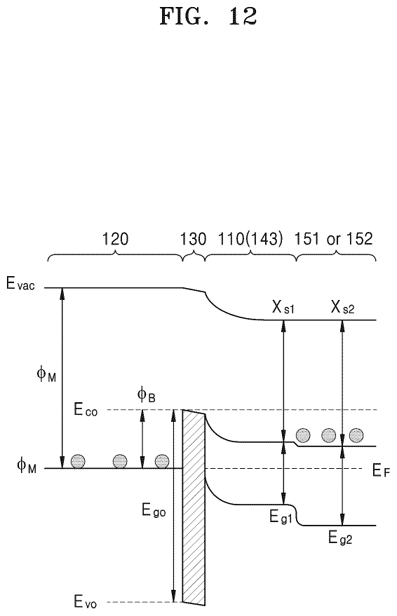

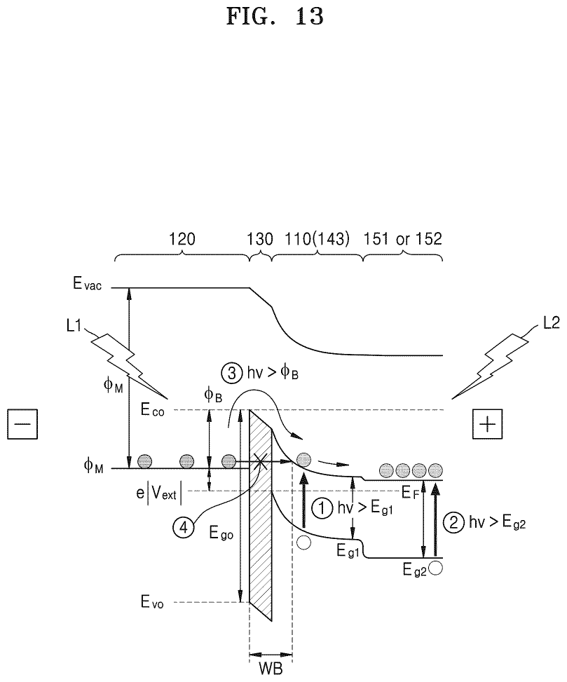

FIG. 12 is an energy band diagram illustrating a state in which a bias voltage is not applied to the implementation examples of the photodetector device that are shown in FIGS. 10 and 11 according to one or more embodiments. FIG. 13 is an energy band diagram illustrating a state in which a reverse bias voltage is applied to the implementation examples of the photodetector device that are shown in FIGS. 10 and 11 according to one or more embodiments. The definitions of symbols shown in FIGS. 12 and 13 are as follows.
φ_{M}: The work function of the conductive layer 120;
φ_{B}: Schottky barrier height;
E_{vac}: Vacuum energy level;
E_{co}: The conduction band energy level of the tunneling barrier layer 130;
Eᵥₒ: The valence band energy level of the tunneling barrier layer 130;
E_{go}: The bandgap energy of the tunneling barrier layer 130;
E_{F}: The Fermi energy level of the n-Ge layer 143;
E_{g1}: The bandgap energy of the n-Ge layer 143;
E_{g2}: The bandgap energy of the semiconductor layer 151 or the doped region 152;
χₛ₁: The electron affinity of the n-Ge layer 143;
χₛ₂: The electron affinity of the semiconductor layer 151 or the doped region 152;
e|Vext|: Energy by a reverse bias voltage; and
hv: Energy of incident light

For example, in FIGS. 12 and 13, the conductive layer 120 includes ITO, the tunneling barrier layer 130 includes TiO₂, and the semiconductor substrate 150 includes Si. The bandgap energy E_{g} of Ge is 0.67 eV, the electron affinity χₛ₁ of Ge is 4.0 eV, the electron affinity χₛ₂ of Si is 4.05 eV, and the work function φ_{M} of ITO is 4.7 eV. The Schottky barrier height φ_{B}=φ_{M}−χₛ₁=4.7 eV−4.0 eV=0.7 eV.

When a reverse bias voltage is applied, the Fermi energy level E_{F} of the n-Ge layer 143 falls by the amount of energy (e|Vext|) provided by the reverse bias voltage as shown in FIG. 13. Ge has less bandgap energy than Si, thereby facilitating the absorption of NIR or SWIR rays. Therefore, when the energy of incident light is greater than the bandgap energy of the n-Ge layer 143 (hv>E_{g1}) as indicated by reference numeral \textcircled{1} in FIG. 13, photocurrent flowing by interband transition is detectable. In addition, when visible light is incident and the energy of the incident light is greater than the bandgap energy of the semiconductor layer 151 or the doped region 152 (hv>E_{g2}) as indicated by reference numeral \textcircled{2} in FIG. 13, photocurrent occurring by interband transition may be detected in the semiconductor layer 151 or the doped region 152. In addition, when the energy of the incident light is greater than the Schottky barrier height φ_{B} formed between the conductive layer 120 and the Ge semiconductor layer 110 (hv>φ_{B}) as indicated by reference numeral \textcircled{3} in FIG. 13, the conductive layer 120 may absorb some of the incident light, and thus, hot carriers are formed by the internal quantum emission effect, generating a photocurrent. Therefore, according to the implementation examples of the photodetector device shown in FIGS. 10 and 11, light is detectable not only in the NIR band and the SWIR band, but also in the visible light band. In addition, due to the tunneling barrier layer 130, the thickness of the Schottky barrier may be increased as indicated by WB in FIG. 13 with substantially no effect on the Schottky barrier height between the conductive layer 120 and the Ge semiconductor layer 110. As a result, as indicated by reference numeral \textcircled{4} in FIG. 13, electron tunneling is reduced or prevented, and thus, dark current may be reduced or prevented.

In addition, according to one or more embodiments, the n-Ge layer 143 may include the nanostructures 111 having a period, a width, and a thickness that are each less than the wavelength of incident light, and thus, the light absorption rate of the inside of the n-Ge layer 143 may be improved in a wide wavelength band (for example, in the NIR or SWIR band) due to the electric field confinement effect.

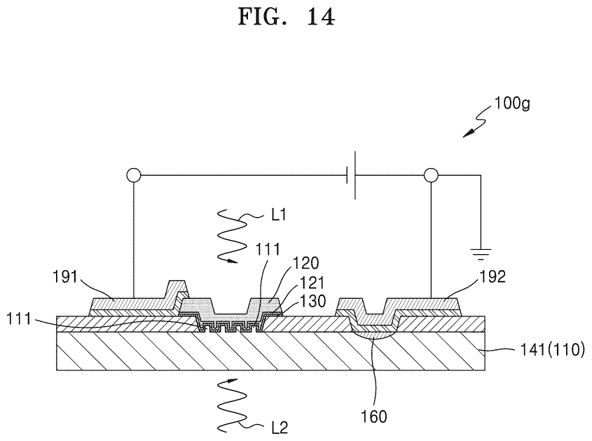

FIG. 14 is a cross-sectional view illustrating an implementation example of a photodetector device 100g according to one or more embodiments. The implementation example shown in FIG. 14 is different from the implementation example shown in FIG. 6 in that the intermediate layer 121 is provided between the conductive layer 120 and the tunneling barrier layer 130.

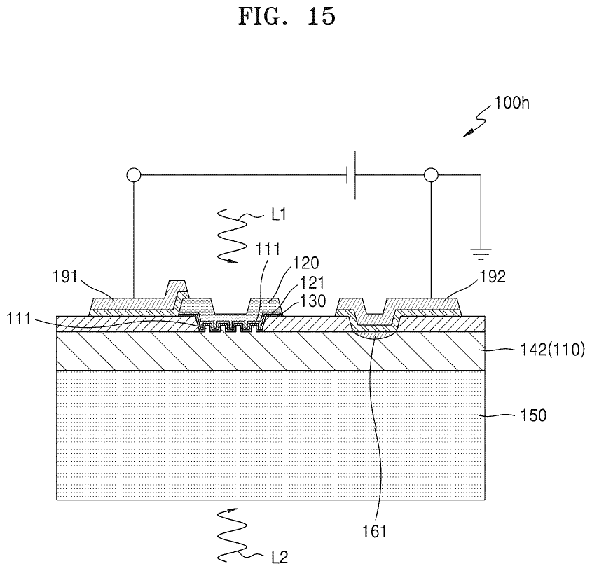

FIG. 15 is a cross-sectional view illustrating an embodiment of a photodetector device 100h according to one or more embodiments. The implementation shown in FIG. 15 is different from the implementation shown in FIG. 7 in that the intermediate layer 121 is provided between the conductive layer 120 and the tunneling barrier layer 130. Therefore, the descriptions given with reference to FIGS. 6 and 7 are also applied to the implementation examples shown in FIGS. 14 and 15 unless contradictory thereto. In FIGS. 6, 7, 14, and 15, like reference numerals denote like elements, and repeated descriptions thereof are omitted.

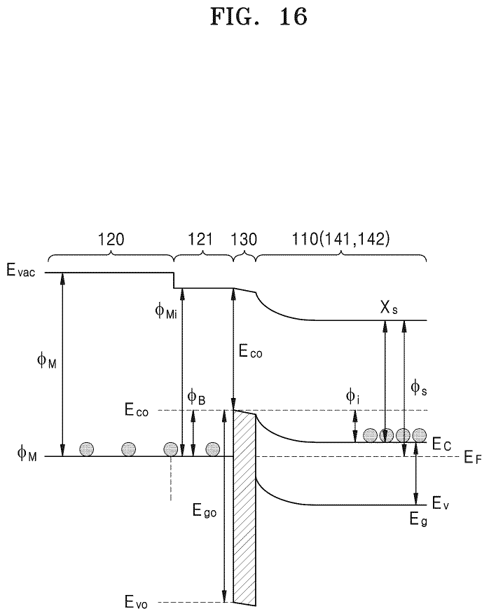

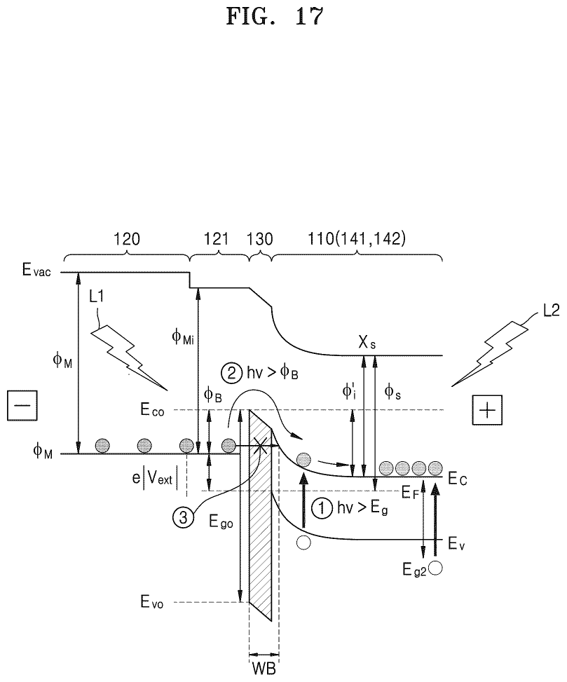

FIG. 16 is an energy band diagram illustrating a state in which a bias voltage is not applied to the implementation examples of the photodetector device that are shown in FIGS. 14 and 15 according to one or more embodiments. FIG. 17 is an energy band diagram illustrating a state in which a reverse bias voltage is applied to the implementation examples of the photodetector device that are shown in FIGS. 14 and 15 according to one or more embodiments. The definitions of symbols shown in FIGS. 16 and 17 are as follows.
φ_{Mi}: The work function of the intermediate layer 121;
φ_{M}: The work function of the conductive layer 120;
φ_{B}: Schottky barrier height;
E_{vac}: Vacuum energy level;
E_{co}: The conduction band energy level of the tunneling barrier layer 130;
Eᵥₒ: The valence band energy level of the tunneling barrier layer 130;
E_{go}: The bandgap energy of the tunneling barrier layer 130;
E_{c}: The conduction band energy level of the Ge semiconductor layer 110;
Eᵥ: The valence band energy level of the Ge semiconductor layer 110;
E_{F}: The Fermi energy level of the Ge semiconductor layer 110;
E_{g}: The bandgap energy of the Ge semiconductor layer 110;
χₛ: The electron affinity of the Ge semiconductor layer 110;
ϕₛ: The work function of the Ge semiconductor layer 110;
ϕᵢ: The built-in potential of the Ge semiconductor layer 110 when no bias voltage is applied;
ϕᵢ′: The built-in potential of the Ge semiconductor layer 110 when a reverse bias voltage is applied;
e|Vext|: Energy by a reverse bias voltage; and
hv: Energy of incident light.

For example, in FIGS. 14 and 15, the Ge semiconductor layer 110 includes n-Ge, the intermediate layer 121 includes TiN, the conductive layer 120 includes ITO, and the tunneling barrier layer 130 includes TiO₂. The bandgap energy E_{g} of Ge is 0.67 eV, the electron affinity χₛ of Ge is 4.0 eV, the work function φ_{Mi} of TiN is 4.5 eV, and the work function φ_{M} of ITO is 4.7 eV. Therefore, Equation (1) is satisfied. The Schottky barrier height φ_{B}=φ_{Mi}−χₛ=4.5 eV−4.0 eV=0.5 eV. The Schottky barrier height is less than the Schottky barrier height, 0.7 eV, at the ITO/n-GE interface described above. Because the conduction band energy level of TiO₂ is substantially the same as the conduction band energy of n-Ge, the tunneling barrier layer 130 has substantially no effect on the Schottky barrier height.

When a reverse bias voltage is applied, the Fermi energy level E_{F} of the Ge semiconductor layer 110 falls by the amount of energy (e|Vext|) provided by the reverse bias voltage as shown in FIG. 17. Ge has less bandgap energy than Sit, thereby facilitating the absorption of NIR or SWIR rays. Therefore, when the energy of incident light is greater than the bandgap energy of the Ge semiconductor layer 110 (hv>Eg) as indicated by reference numeral \textcircled{1} in FIG. 17, photocurrent flowing by interband transition is detectable. In addition, when the energy of incident light is greater than the Schottky barrier height φ_{B} formed between the intermediate layer 121 and the Ge semiconductor layer 110 (hv>φ_{B}) as indicated by reference numeral \textcircled{2} in FIG. 17, the conductive layer 120 may absorb some of the incident light, and thus, hot carriers are formed by the internal quantum emission effect, generating a photocurrent. As described above, because photocurrent is generated by interband transition and internal quantum emission, NIR rays or SWIR rays having relatively low energy may be effectively detected. In addition, due to the tunneling barrier layer 130, electron tunneling may be reduced or prevented to reduce or prevent the occurrence of dark current while having substantially no effect on the Schottky barrier height between the conductive layer 120 and the Ge semiconductor layer 110 as indicated by reference numeral \textcircled{3} in FIG. 17.

In addition, according to one or more embodiments, the Ge semiconductor layer 110 may include the nanostructures 111 having a period, a width, and a thickness that are each less than the wavelength of incident light, and thus, the light absorption rate of the inside of the Ge semiconductor layer 110 may be improved in a wide wavelength band (for example, in the NIR or SWIR band) due to the electric field confinement effect.

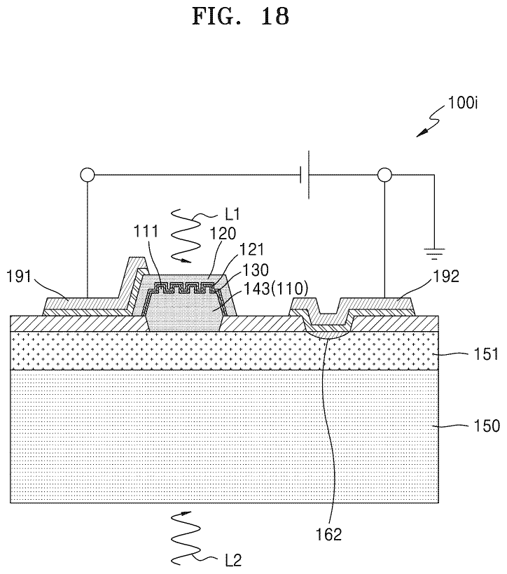

FIG. 18 is a cross-sectional view illustrating an implementation example of a photodetector device 100i according to one or more embodiments. The implementation example shown in FIG. 18 is different from the implementation example shown in FIG. 10 in that the intermediate layer 121 is provided between the conductive layer 120 and the tunneling barrier layer 130.

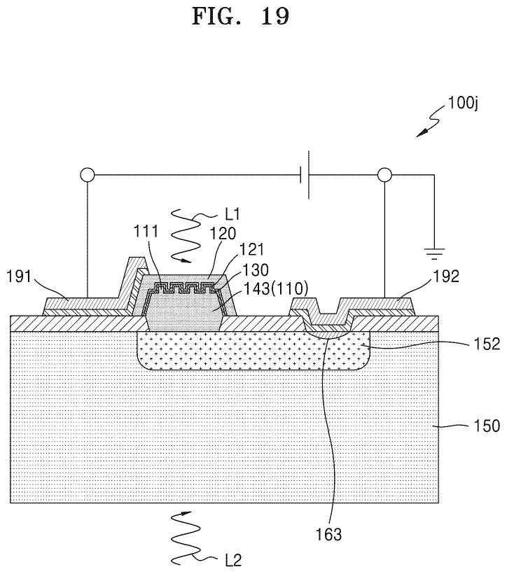

FIG. 19 is a cross-sectional view illustrating an implementation example of a photodetector device 100j according to one or more embodiments. The implementation example shown in FIG. 19 is different from the implementation example shown in FIG. 11 in that the intermediate layer 121 is provided between the conductive layer 120 and the tunneling barrier layer 130. Therefore, the descriptions given with reference to FIGS. 10 and 11 are also applied to the implementation examples shown in FIGS. 18 and 19 unless contradictory thereto. In FIGS. 10, 11, 18, and 19, like reference numerals denote like elements, and repeated descriptions thereof are omitted.

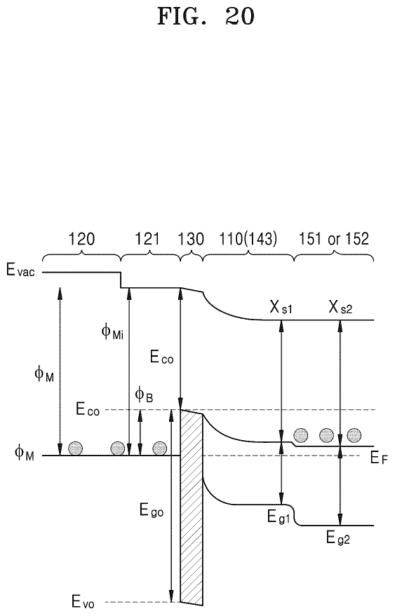

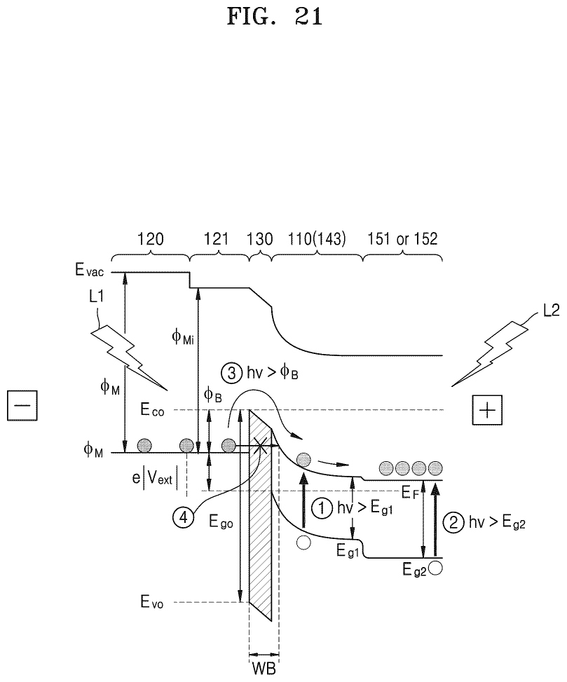

FIG. 20 is an energy band diagram illustrating a state in which a bias voltage is not applied to the implementation examples of the photodetector device that are shown in FIGS. 18 and 19 according to one or more embodiments. FIG. 21 is an energy band diagram illustrating a state in which a reverse bias voltage is applied to the implementation examples of the photodetector device that are shown in FIGS. 18 and 19 according to one or more embodiments. The definitions of symbols shown in in FIGS. 20 and 21 are as follows.
φ_{Mi}: The work function of the intermediate layer 121;
φ_{M}: The work function of the conductive layer 120;
φ_{B}: Schottky barrier height;
E_{vac}: Vacuum energy level;
E_{co}: The conduction band energy level of the tunneling barrier layer 130;
Eᵥₒ: The valence band energy level of the tunneling barrier layer 130;
E_{go}: The bandgap energy of the tunneling barrier layer 130;
E_{F}: The Fermi energy level of the Ge semiconductor layer 110;
E_{g1}: The bandgap energy of the Ge semiconductor layer 110;
E_{g2}: The bandgap energy of the semiconductor layer 151 or the doped region 152;
χₛ₁: The electron affinity of the Ge semiconductor layer 110;
χₛ₂: The electron affinity of the semiconductor layer 151 or the doped region 152;
e|Vext|: Energy by a reverse bias voltage; and
hv: Energy of incident light.

For example, in FIGS. 20 and 21, the Ge semiconductor layer 110 includes n-Ge, the intermediate layer 121 includes TiN, the conductive layer 120 includes ITO, the tunneling barrier layer 130 includes TiO₂, and the semiconductor substrate 150 includes Si. The bandgap energy E_{g1} of Ge is 0.67 eV, the electron affinity χₛ₁ of Ge is 4.0 eV, the electron affinity χₛ₂ of Si is 4.05 eV, the work function φ_{Mi} of TiN is 4.5 eV, and the work function φ_{M} of ITO is 4.7 eV. Therefore, Equation (1) is satisfied. The Schottky barrier height φ_{B}=φ_{M}i−χₛ₁=4.5 eV−4.0 eV=0.5 eV. The Schottky barrier height is less than the Schottky barrier height, 0.7 eV, at the ITO/n-GE interface described above. Because the conduction band energy level of TiO₂ is substantially the same as the conduction band energy of n-Ge, the tunneling barrier layer 130 has substantially no effect on the Schottky barrier height.

When a reverse bias voltage is applied, the Fermi energy level E_{F} of the Ge semiconductor layer 110 falls by the amount of energy (e|Vext|) provided by the reverse bias voltage as shown in FIG. 21. Ge has less bandgap energy than Si, thereby facilitating the absorption of NIR or SWIR rays. Therefore, when the energy of incident light is greater than the bandgap energy of the Ge semiconductor layer 110 (hv>E_{g1}) as indicated by reference numeral \textcircled{1} in FIG. 21, photocurrent flowing by interband transition is detectable. In addition, when visible light is incident and the energy of the incident light is greater than the bandgap energy of the semiconductor layer 151 or the doped region 152 (hv>E_{g2}) as indicated by reference numeral \textcircled{2} in FIG. 21, photocurrent occurring by interband transition may be detected in the semiconductor layer 151 or the doped region 152. In addition, when the energy of the incident light is greater than the Schottky barrier height φ_{B} formed between the intermediate layer 121 and the Ge semiconductor layer 110 (hv>φ_{B}) as indicated by reference numeral \textcircled{3} in FIG. 21, the intermediate layer 121 may absorb some of the incident light, and thus, hot carriers are formed by the internal quantum emission effect, generating a photocurrent. Therefore, according to the implementation examples of the photodetector device shown in FIGS. 18 and 19, light is detectable not only in the NIR band and the SWIR band, but also in the visible light band. In addition, due to the tunneling barrier layer 130, the thickness of the Schottky barrier may be increased as indicated by WB in FIG. 21 with substantially no effect on the Schottky barrier height between the intermediate layer 121 and the Ge semiconductor layer 110. As a result, as indicated by reference numeral \textcircled{4} in FIG. 21, electron tunneling is reduced or prevented, and thus, dark current may be reduced or prevented.

In addition, according to one or more embodiments, the Ge semiconductor layer 110 may include the nanostructures 111 having a period, a width, and a thickness that are each less than the wavelength of incident light, and thus, the light absorption rate of the inside of the Ge semiconductor layer 110 may be improved in a wide wavelength band (for example, in a NIR or SWIR band) due to the electric field confinement effect.

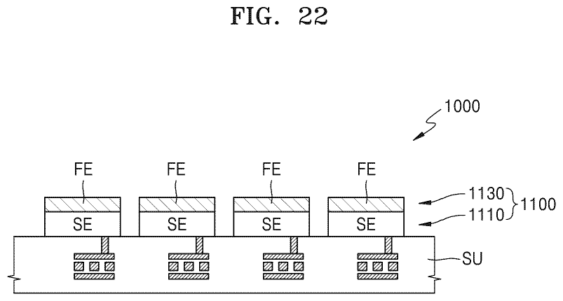

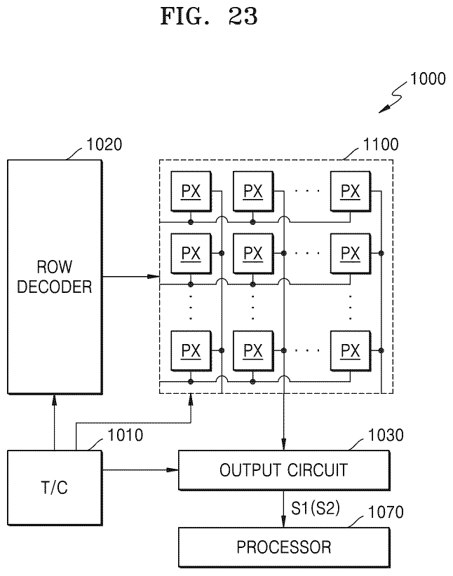

FIG. 22 is a cross-sectional view illustrating an image sensor according to one or more embodiments. FIG. 23 is a block diagram illustrating a circuit configuration of an image sensor according to one or more embodiments.

Referring to FIGS. 22 and 23, the image sensor 1000 may include a pixel array 1100 including a plurality of pixels PX. The pixel array 1100 may include a sensor array 1110 including a plurality of light-sensing elements SE. The photodetector device 100 may be employed as the light-sensing elements SE of the sensor array 1110. A separation layer may be formed between adjacent light-sensing elements SE. A filter array 1130 including a plurality of filter elements FE respectively facing the plurality of light-sensing elements SE may be provided on the sensor array 1110. The filter elements FE may each be a band-pass filter through which light passes in a given wavelength band, and the wavelength band of the filter elements FE may be set according to the types of images to be acquired by the image sensor 1000. For example, the filter elements FE may each be a band-pass filter through which light passes in the visible light band or the infrared band. The filter array 1130 may include filter elements FE of different types to pass light in a plurality of wavelength bands. The filter array 1130 may include general color filters. Hereinafter, a light-sensing element SE and a filter element FE corresponding to the light-sensing element SE may be referred to as a pixel PX.

The image sensor 1000 may include a circuit unit including circuit elements that are respectively connected to the light-sensing elements SE and configured to read a photoelectric signal generated from each of the light-sensing elements SE. At least a portion of the circuit unit may be provided in a circuit board SU shown in FIG. 22, and the light-sensing elements SE may be provided on the circuit board SU in connection with the circuit elements of the circuit unit that are provided in the circuit board SU. The image sensor 1000 may include the pixel array 1100, a timing controller (T/C) 1010, a row decoder 1020, an output circuit 1030, and a processor 1070. The T/C 1010, the row decoder 1020, the output circuit 1030, and the processor 1070 may be implemented as one chip or as separate chips.

The pixels PX of the pixel array 1100 may be two-dimensionally arranged in a plurality of rows and columns. The row decoder 1020 may select one of the rows of the pixel array 1100 in response to a row address signal output from the T/C 1010. The output circuit 1030 may output light-sensing signals from a plurality of pixels arranged in the selected row in units of columns. To this end, the output circuit 1030 may include a column decoder and an analog-to-digital converter (ADC). For example, the output circuit 1030 may include a plurality of ADCs respectively provided for the columns between the column decoder and the pixel array 1100, or one ADC provided at an output terminal of the column decoder.

The processor 1070 may process an electrical signal output from the output circuit 1030 to form an image. According to one or more embodiments, each of the pixels PX of the image sensor 1000 may use the photodetector device 100 capable of sensing light in both the visible light band and the infrared band as the light-sensing element SE, and thus, an electrical signal output from the output circuit 1030 may include a photoelectric signal S1 generated by visible light and/or a photoelectric signal S2 generated by infrared light. Accordingly, the processor 1070 may process such signals to form a visible light image and/or an infrared image, and may form a 3D image. For example, a two-dimensional (2D) image may be formed using the photoelectric signal S1 generated by visible light, information on the depth of each position of the 2D image may be calculated by a method such as a time of flight (ToF) method using the photoelectric signal S2 generated by infrared light, and the depth information may be combined with the 2D to form a three-dimensional (3D) image. Because the photodetector device 100 is also capable of sensing light in the ultraviolet band, the processor 1070 may also form an ultraviolet image.

As described above, according to one or more embodiments, light may be detected in the NIR and SWIR bands due to the Schottky junction structure using Ge, and the light absorption rate of the photodetector device 100 may be improved due to the nanostructures 111 provided on the Ge semiconductor layer 110. In addition, due to the tunneling barrier layer 130 between the Ge semiconductor layer 110 and the conductive layer 120, the thickness of the Schottky barrier may be increased to reduce or prevent dark current caused by quantum mechanical tunneling of majority carriers.

Photodetector devices 100-100j are described and depicted throughout the disclosure, and these photodetector devices are exemplary and not exclusive. Aspects of each photodetector device may be combined or implemented with other aspects of other photodetector devices disclosed herein without departing from the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A photodetector device comprising:
a germanium semiconductor layer comprising a plurality of nanostructures at an upper surface of the germanium semiconductor layer;
a conductive layer on the plurality of nanostructures, the conductive layer and the germanium semiconductor layer forming a first Schottky junction; and
a tunneling barrier layer between the germanium semiconductor layer and the conductive layer.

2. The photodetector device of claim 1, wherein the plurality of nanostructures comprise nanodisks or nanoholes.

3. The photodetector device of claim 1, wherein the plurality of nanostructures are arranged at a period p in a first direction that is parallel to the upper surface of the germanium semiconductor layer, and
wherein each nanostructure of the plurality of nanostructures has a width d in the first direction and a thickness t in a second direction perpendicular to the first direction.

4. The photodetector device of claim 3, wherein the period p of the plurality of nanostructures satisfies λ/5<p<λ, where λ corresponds to a wavelength of incident light.

5. The photodetector device of claim 3, wherein the width d of each nanostructure of the plurality of nanostructures satisfies λ/4n<d<4λ/n, where λ corresponds to a wavelength of incident light and n corresponds to a refractive index of the germanium semiconductor layer.

6. The photodetector device of claim 3, wherein the thickness t of each nanostructure of the plurality of nanostructures satisfies λ/4n<t<4λ/n, where λ corresponds to a wavelength of incident light and n corresponds to a refractive index of the germanium semiconductor layer.

7. The photodetector device of claim 1, wherein the germanium semiconductor layer is doped with a dopant.

8. The photodetector device of claim 1, further comprising a first semiconductor substrate,
wherein the germanium semiconductor layer is on the first semiconductor substrate.

9. The photodetector device of claim 8, wherein the first semiconductor substrate is of a first conductivity type,
wherein the photodetector device further comprises a second semiconductor layer between the first semiconductor substrate and the germanium semiconductor layer,
wherein the second semiconductor layer is of a second conductivity type that is different from the first conductivity type.

10. The photodetector device of claim 8, wherein the first semiconductor substrate is doped with a first conductivity type dopant, and
wherein a region of the first semiconductor substrate that contacts the germanium semiconductor layer is doped with a second conductivity type dopant.

11. The photodetector device of claim 1, wherein the conductive layer comprises a metal or a metal oxide.

12. The photodetector device of claim 1, wherein the conductive layer comprises a transparent conductive oxide (TCO).

13. The photodetector device of claim 1, further comprising an intermediate layer between the tunneling barrier layer and the conductive layer.

14. The photodetector device of claim 13, wherein the intermediate layer and the germanium semiconductor layer form a second Schottky junction, and
wherein the intermediate layer has a work function such that a Schottky barrier height of the second Schottky junction is less than a Schottky barrier height of the first Schottky junction.

15. The photodetector device of claim 1, wherein a difference between a conduction band energy level of the tunneling barrier layer and an electron affinity of the germanium semiconductor layer is less than 2 eV.

16. The photodetector device of claim 1, wherein a bandgap energy of the tunneling barrier layer is greater than a bandgap energy of the germanium semiconductor layer.

17. The photodetector device of claim 1, wherein the tunneling barrier layer comprises a metal oxide or a silicon oxide.

18. An image sensor comprising:
a sensor array comprising a plurality of light-sensing elements, each light-sensing element of the plurality of light-sensing elements comprising a photodetector device; and
a processor configured to read a photoelectric signal generated by each light-sensing element of the plurality of light-sensing elements,
wherein each photodetector device comprises:
a germanium semiconductor layer comprising a plurality of nanostructures at an upper surface of the germanium semiconductor layer;
a conductive layer on the plurality of nanostructures, the conductive layer and the germanium semiconductor layer forming a first Schottky junction; and
a tunneling barrier layer between the germanium semiconductor layer and the conductive layer.

19. The image sensor of claim 18, wherein each photodetector device further comprises an intermediate layer between the tunneling barrier layer and the conductive layer.

20. The image sensor of claim 19, wherein the intermediate layer and the germanium semiconductor layer form a second Schottky junction, and
wherein the intermediate layer has a work function such that a Schottky barrier height of the second Schottky junction is less than a Schottky barrier height of the first Schottky junction.

21. A photodetector device, comprising:
a germanium semiconductor layer comprising a plurality of nanostructures at an upper surface of the germanium semiconductor layer;
a conductive layer on the plurality of nanostructures, the conductive layer and the germanium semiconductor layer forming a first Schottky junction; and
a tunneling barrier layer between the germanium semiconductor layer and the conductive layer,
wherein the germanium semiconductor layer is doped with an n-type dopant at a first concentration.

22. The photodetector device of claim 21, further comprising an intermediate layer between the tunneling barrier layer and the conductive layer,
wherein the intermediate layer and the germanium semiconductor layer form a second Schottky junction.

23. The photodetector device of claim 22, further comprising:
a first electrode contacting the conductive layer; and
a second electrode contacting the germanium semiconductor layer.

24. The photodetector device of claim 23, wherein the germanium semiconductor layer comprises an ohmic contact region doped with an n-type dopant at a second concentration higher than the first concentration, and
wherein the second electrode contacts the ohmic contact region of the germanium semiconductor layer.

25. The photodetector device of claim 21, further comprising:
a first electrode contacting the conductive layer; and
a second electrode contacting the germanium semiconductor layer,
wherein the germanium semiconductor layer comprises an ohmic contact region doped with an n-type dopant at a second concentration higher than the first concentration, and
wherein the second electrode contacts the ohmic contact region of the germanium semiconductor layer.
